(19) United States
(12) Patent Application Publication
(10) Pub. No.: US 2026/0181821 A1
(43) Pub. Date: Jun. 25, 2026

(54) ELECTRONIC APPARATUS WITH HEAT EXCHANGE UNIT

(71) Applicant: BE RICH LIMITED, Taipei City (TW)

(72) Inventor: Shen-Jen LIN, Taipei City (TW)

(21) Appl. No.: 19/089,808

(22) Filed: Mar. 25, 2025

(30) Foreign Application Priority Data
Dec. 23, 2024 (TW) 113150199

(51) Int. Cl. H05K 7/20; G06F 1/20

(52) U.S. Cl. CPC H05K 7/20236; G06F 1/20; H05K 7/20272; G06F 2200/201; H05K 7/202

(57) ABSTRACT

An electronic apparatus includes a case component, an electronic module, and a heat exchange unit. The case component surrounds and defines an accommodation space. The electronic module is disposed in the accommodation space and includes a base board, and a plurality of electronic devices that are disposed on the base board. The heat exchange unit is disposed in the case component and includes a supercritical fluid that is received by the accommodation space. The electronic module is submerged in the supercritical fluid of the heat exchange unit allowing heat exchange to occur between the electronic module and the supercritical fluid.

### CROSS-REFERENCE TO RELATED APPLICATION

This application claims priority to Taiwanese Invention Patent Application No. 113150199, filed on Dec. 23, 2024, the entire disclosure of which is incorporated by reference herein.

### FIELD

The disclosure relates to an electronic apparatus, and more particularly to an electronic apparatus with a heat exchange unit. The electronic apparatus may be a data processing device.

### BACKGROUND

A conventional motherboard as disclosed in TW201928582A includes a circuit board, a central processor, a plurality of electronic components, a heat sink, a plurality of fan modules, and a control circuit. The heat sink has a plurality of heat dissipation areas. The fan modules are respectively installed in the heat dissipation areas which are located near the electronic components to facilitate cooling thereof. The control circuit signally communicates the electronic components with the fan modules.

The control circuit is used to detect the operating status of the electronic components, and controls operation of the fan modules in the heat dissipation areas based on the operating status of the electronic components. This allows the conventional motherboard to direct targeted cooling toward the electronic components near the heat dissipation areas. However, the conventional motherboard has the drawback that the space near the top of the conventional motherboard needs to be vacant for the installation of the fan modules. This decreases the freedom to install other components in that space. Additionally, the installation of the fan modules increase the size and weight of the conventional motherboard.

Furthermore, it should be noted that as the thermal design power (TDP) of CPUs and GPUs have increased to over several thousand Watts, maximum achievable heat dissipation of the conventional fan modules may only reach around 750 Watts. This leads to insufficient cooling capability and operational inefficiency in conventional motherboards.

### SUMMARY

Therefore, an object of the disclosure is to provide an electronic apparatus that can alleviate at least one of the drawbacks of the prior art.

According to the disclosure, the electronic apparatus includes a case component, an electronic module, and a heat exchange unit. The case component surrounds and defines an accommodation space. The electronic module is disposed in the accommodation space, and includes a base board and a plurality of electronic devices that are disposed on the base board. The heat exchange unit is disposed in the case component and includes a supercritical fluid that is received by the accommodation space. The electronic module is submerged in the supercritical fluid of the heat exchange unit allowing heat exchange to occur between the electronic module and the supercritical fluid.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross-sectional view illustrating a first embodiment of an electronic apparatus according to the present disclosure.

FIG. 2 is a fragmentary schematic cross-sectional view illustrating a second embodiment of the electronic apparatus according to the present disclosure.

FIG. 3 is a schematic cross-sectional view illustrating a third embodiment of the electronic apparatus according to the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

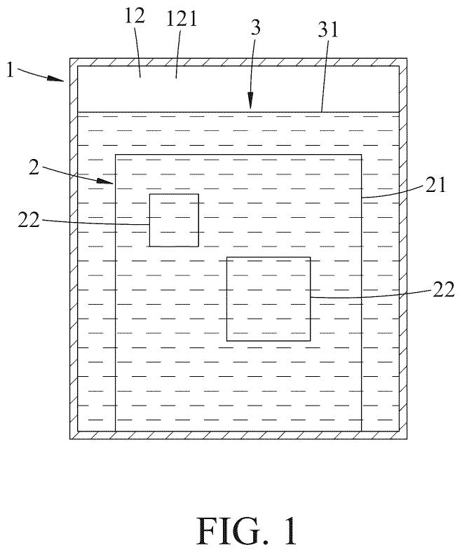

Referring to FIG. 1, a first embodiment of an electronic apparatus according to the present disclosure includes a case component 1, an electronic module 2, and a heat exchange unit 3. In some embodiments, the electronic apparatus may be a data processing device. However, the electronic apparatus is not limited to this example.

The case component 1 surrounds and defines an accommodation space 12.

The electronic module 2 is disposed in the accommodation space 12, and includes a base board 21 and a plurality of electronic devices 22 that are disposed on the base board 21. In this embodiment, the base board 21 is a mainboard (MB).

It should be noted that the plurality of electronic devices 22 may be graphic processing units (GPUs), central processing units (CPUs), servers, random access memories (RAMs), solid-state disks (SSDs), or hard disk drives (HDDs). It should be noted that, in this embodiment, the electronic module 2 includes two electronic devices 22 (see FIG. 1); however, this is not a limitation of the disclosure, and the amount of electronic devices 22 may be designed according to user requirements.

The heat exchange unit 3 is disposed in the case component 1 and includes a supercritical fluid 31 that is received by the accommodation space 12. In other words, the supercritical fluid 31 is filled in the accommodation space 12. The electronic module 2 is submerged in the supercritical fluid 31 of the heat exchange unit 3, thereby allowing heat exchange to occur between the electronic module 2 and the supercritical fluid 31. More specifically, the supercritical fluid 31 also conducts heat exchange between the case component 1 and the electronic module 2.

Table 1 shows the physical properties of carbon dioxide in a gaseous state, a supercritical state, and a fluid state.

TABLE 1

| Physical properties of | Gaseous | Supercritical | Fluid |
|---|---|---|---|
| carbon dioxide | state | state | state |
| Density (kg/m³) | 0.6-1.0 | 200-900 | 1000 |
| Viscosity (cP) | 0.1 | 0.1-0.01 | 0.01 |
| Mass diffusivity (mm²/s) | 1-10 | 0.01-0.1 | 0.001 |

Table 2 compares the physical properties of supercritical carbon dioxide with two other liquid coolant materials.

TABLE 2

| Physical | | | Supercritical |
|---|---|---|---|
| properties | Mineral oil | Fluoride | carbon dioxide |
| Density (kg/m³) | 800-900 | 1500-1800 | 200-900 |
| Specific heat | 2000 | 900-1100 | 300-600 |
| capacity (J/kg · | | | |
| K) | | | |
| Thermal | 0.11-0.15 | 0.06-0.07 | 0.001-0.1 |
| conductivity | | | |
| (W/m · K) | | | |
| Viscosity (cP) | 5-10 | 1.8-2.5 | 0.01-0.1 |

Because the supercritical carbon dioxide has physical properties such as viscosity and mass diffusivity that is in-between that of carbon dioxide in the gaseous state and the fluid state, the supercritical carbon dioxide may quickly diffuse and contact the electronic module 2. Furthermore, in comparison with common coolants such as mineral oil or fluoride, the supercritical carbon dioxide has physical properties such as low density and low specific heat capacity which offers advantages such as lower weight and quicker heat transfer. This allows the supercritical carbon dioxide to quickly conduct heat exchange with the electronic module 2. The supercritical carbon dioxide may have the advantage of evenly conducting heat to the electronic module 2 or evenly dissipating heat from the electronic module 2.

The accommodation space 12 includes a top area 121 that is not filled with the supercritical fluid 31. A pressure in the accommodation space 12 is no less than a critical pressure of the supercritical fluid 31.

In the first embodiment, the supercritical fluid 31 is carbon dioxide with a supercritical pressure of 7.38 MPa and a supercritical temperature of 31.1° C. Furthermore, in the first embodiment, the pressure of the accommodation space 12 is no less than the supercritical pressure of carbon dioxide which is 7.38 MPa. Carbon dioxide has low chemical reactivity and is not electrically conductive. Therefore, having the electronic module 2 submerged in the supercritical carbon dioxide is safer since it is unlikely to react with the electronic module 2 upon contact thereof.

When the temperature of the electronic module 2 becomes lower than that of the supercritical fluid 31, the electronic module 2 will be evenly heated until its temperature is close to the temperature of the supercritical fluid 31. On the other hand, when the temperature of the electronic module 2 becomes higher than that of the supercritical fluid 31, the supercritical fluid 31 may evenly dissipate heat from the electronic module 2 until the temperature of the electronic module 2 is close to that of the supercritical fluid 31. In practice, the electronic module 2 usually has an operating temperature that is above 40° C. Therefore, in this embodiment, carbon dioxide is chosen as the supercritical fluid 31 since it has a supercritical temperature of 31.1° C. and can evenly dissipate heat from the electronic module 2.

In some variations of the embodiment, the electronic module 2 may have a different operating temperature, and a different material with a different supercritical temperature may be chosen as the supercritical fluid 31 to achieve even heating or dissipation of the electronic module 2. In such variations, the supercritical fluid 31 of the heat exchange unit 3 may be methane, ethane, propane, ethylene, propylene, methanol, ethanol, acetone, or combinations thereof.

In the first embodiment, the case component 1 is made of metal and has relatively high thermal conductivity. The relatively high thermal conductivity of the case component 1 allows the temperature of all the components (e.g., the electronic devices 22) of the electronic module 2 to efficiently reach thermal equilibrium. However, in other variations of the embodiment, the case component 1 may be made of a polymer material or a fiber-reinforced plastic (FRP) material.

The polymer material may be, including but not limited to, polypropylene (PP), polyamide (PA) (commonly known as nylon), polyphenylene sulfide (PPS), polyetheretherketone (PEEK), or polybenzimidazole (PBI). The FRP may be, including but not limited to, carbon fiber reinforced polypropylene, glass fiber reinforced polypropylene, carbon fiber reinforced polyamide, glass fiber reinforced polyamide, carbon fiber reinforced polyphenylene sulfide, glass fiber reinforced polyphenylene sulfide, carbon fiber reinforced polyetheretherketone, glass fiber reinforced polyetheretherketone, carbon fiber reinforced polybenzimidazole, or glass fiber reinforced polybenzimidazole. By selecting the polymer or FRP materials each having a relatively low density, the overall weight of the case component 1 may be decreased. In certain embodiments, the case component 1 is made of polypropylene.

In this embodiment, the electronic module 2 is submerged in the supercritical fluid 31 of the heat exchange unit 3, thereby allowing more efficient heat exchange to occur between the electronic module 2 and the supercritical fluid 31, and decreasing the overall energy consumption of the electronic module 2.

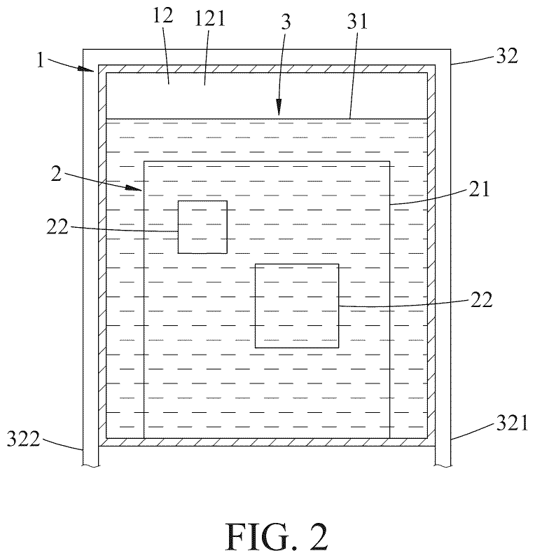

Referring to FIG. 2, a second embodiment of the electronic apparatus according to the present disclosure is similar to the first embodiment; however, in the second embodiment, the heat exchange unit 3 further includes a heat pipe 32, and a heat exchange fluid (not shown) disposed in the heat pipe 32 to facilitate heat exchange with the heat pipe 32. The heat pipe 32 contacts and surrounds an outer surface of the case component 1, and includes an input end 321 and an output end 322 that is disposed opposite to the input end 321. The heat exchange fluid is inputted into and outputted out of the heat pipe 32 respectively via the input end 321 and the output end 322, and facilitates heat exchange between the case component 1 and the heat pipe 32.

In the second embodiment, both the case component 1 and the heat pipe 32 are made of metal which has relatively high thermal conductivity. However, in other variations of the embodiment, the case component 1 may be made of a polymer material or an FRP material. The polymer material may be, including but not limited to, PP, PA, PPS, PEEK, or PBI. The FRP may be, including but not limited to, carbon fiber reinforced PP, glass fiber reinforced PP, carbon fiber reinforced PA, glass fiber reinforced PA, carbon fiber reinforced PPS, glass fiber reinforced PPS, carbon fiber reinforced PEEK, glass fiber reinforced PEEK, carbon fiber reinforced PBI, or glass fiber reinforced PBI. By selecting the polymer or FRP materials that have a relatively low density, the overall weight of the case component 1 may be decreased.

In the second embodiment, the heat exchange fluid is water which may be set at a specific temperature according to user requirements. By including the heat pipe 32 and the heat exchange fluid, the second embodiment may improve the heat exchange efficiency of the electronic apparatus.

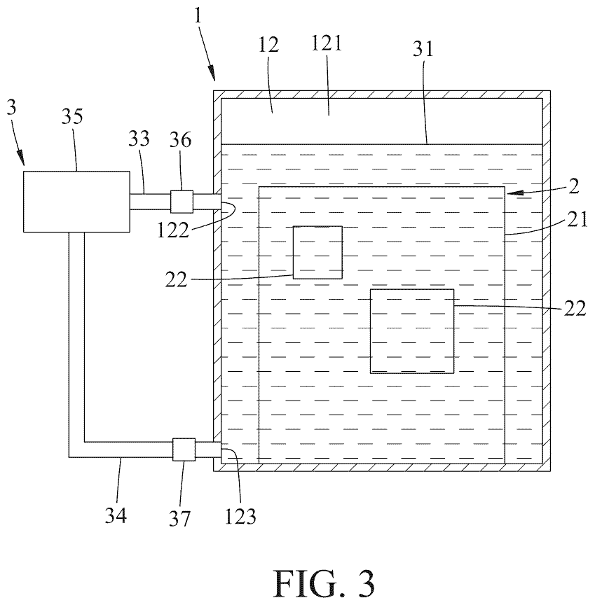

Referring to FIG. 3, a third embodiment of the electronic apparatus is similar to the first embodiment; however, in the third embodiment, the accommodation space 12 includes an outlet opening 122, and an inlet opening 123. The outlet opening 122 is formed on the case component 1, and is fluidly communicating with the accommodation space 12. The inlet opening 123 is formed on the case component 1, is fluidly communicating with the accommodation space 12, and is spaced apart from the outlet opening 122.

In the third embodiment, the case component 1 is made of metal, polymer, or fiber-reinforced plastic. It should be noted that the choice of metal for the case component 1 offers the advantage of providing higher thermal conductivity. The polymer may be, including but not limited to PP, PA, PPS, PEEK, or PBI. The FRP may be, including but not limited to carbon fiber reinforced PP, glass fiber reinforced PP, carbon fiber reinforced PA, glass fiber reinforced PA, carbon fiber reinforced PPS, glass fiber reinforced PPS, carbon fiber reinforced PEEK, glass fiber reinforced PEEK, carbon fiber reinforced PBI, or glass fiber reinforced PBI. By selecting the polymer or FRP materials that have a relatively low density, the overall weight of the case component 1 may be decreased.

Furthermore, in the third embodiment, the heat exchange unit 3 further includes an outlet duct 33, an inlet duct 34, a heat exchanger 35, an outlet check valve 36, and an inlet check valve 37. The outlet duct 33 extends from the outlet opening 122 away from the case component 1. The inlet duct 34 extends from the inlet opening 123 away from the case component 1. The heat exchanger 35 is fluidly connecting the outlet duct 33 and the inlet duct 34. The outlet check valve 36 is mounted on the outlet duct 33 and restricts the supercritical fluid 31 to flow only from the outlet opening 122 toward the heat exchanger 35. The inlet check valve 37 is mounted on the inlet duct 34, and restricts the supercritical fluid 31 to flow only from the heat exchanger 35 toward the inlet opening 123.

In the third embodiment, after heat exchange between the electronic module 2 and the supercritical fluid 31 has occurred, the supercritical fluid 31 carries heat from the electronic module 2, flows from the accommodation space 12 through the outlet duct 33 to the heat exchanger 35, and is cooled before returning to the accommodation space 12 via the inlet duct 34. With the setup as related above, the third embodiment of the present disclosure may have improved heat exchange efficiency.

In summary of the above, in the electronic apparatus of the present disclosure, by having the electronic module 2 submerged in the supercritical fluid 31 and having the supercritical fluid 31 directly contacting the electronic module 2, the supercritical fluid 31 may quickly dissipate heat generated by the electronic module 2 during its operation, and allow the electronic apparatus to achieve high heat exchange efficiency. In addition to the above, this allows the electronic module 2 to achieve thermal equilibrium which improves the operating stability of the various components in the electronic module 2.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. An electronic apparatus comprising:
a case component surrounding and defining an accommodation space;
an electronic module disposed in said accommodation space, and including a base board and a plurality of electronic devices that are disposed on said base board; and
a heat exchange unit disposed in said case component and including a supercritical fluid that is received by said accommodation space, said electronic module being submerged in said supercritical fluid of said heat exchange unit allowing heat exchange to occur between said electronic module and said supercritical fluid.

2. The electronic apparatus as claimed in claim 1, wherein a pressure in said accommodation space is no less than a critical pressure of said supercritical fluid.

3. The electronic apparatus as claimed in claim 1, wherein said supercritical fluid of said heat exchange unit is one of carbon dioxide, methane, ethane, propane, ethylene, propylene, methanol, ethanol, acetone, and combinations thereof.

4. The electronic apparatus as claimed in claim 1, wherein:
said supercritical fluid is carbon dioxide; and
a pressure of said accommodation space is no less than 7.38 MPa.

5. The electronic apparatus as claimed in claim 1, wherein:
said case component is made of metal; and
said supercritical fluid conducts heat exchange between said case component and said electronic module.

6. The electronic apparatus as claimed in claim 1, wherein said heat exchange unit further includes a heat pipe that contacts and surrounds an outer surface of said case component, and that includes an input end and an output end that is disposed opposite to said input end, and
a heat exchange fluid that is disposed in said heat pipe, that is inputted into and outputted out of said heat pipe respectively via said input end and said output end, and that facilitates heat exchange between said case component and said heat pipe.

7. The electronic apparatus as claimed in claim 1, wherein:
said accommodation space includes an outlet opening that is formed on said case component, and that is fluidly communicating with said accommodation space, and an inlet opening that is formed on said case component, that is fluidly communicating with said accommodation space, and that is spaced apart from said outlet opening;
said heat exchange unit further includes an outlet duct that extends from said outlet opening away from said case component, an inlet duct that extended from said inlet opening away from said case component, and a heat exchanger that is fluidly connecting said outlet duct with said inlet duct; and
after heat exchange between said electronic module and said supercritical fluid has occurred, said supercritical fluid carrying heat from said electronic module flows from said accommodation space, through said outlet duct to said heat exchanger, and is cooled before returning to the accommodation space via said inlet duct.

8. The electronic apparatus as claimed in claim 7, wherein said heat exchange unit further includes:
an outlet check valve that is mounted on said outlet duct, and that restricts said supercritical fluid to flow only from said outlet opening toward said heat exchanger; and
an inlet check valve that is mounted on said inlet duct, and that restricts said supercritical fluid to flow only from said heat exchanger toward said inlet opening.

9. The electronic apparatus as claimed in claim 1, wherein said case component is made of metal, polymer, or fiber-reinforced plastic.

10. The electronic apparatus as claimed in claim 9, wherein the polymer is at least one of polypropylene (PP), polyamide (PA), polyphenylene sulfide (PPS), polyetheretherketone (PEEK), or polybenzimidazole (PBI).

11. The electronic apparatus as claimed in claim 9, wherein the fiber-reinforced plastic is at least one of carbon fiber reinforced PP, glass fiber reinforced PP, carbon fiber reinforced PA, glass fiber reinforced PA, carbon fiber reinforced PPS, glass fiber reinforced PPS, carbon fiber reinforced PEEK, glass fiber reinforced PEEK, carbon fiber reinforced PBI, or glass fiber reinforced PBI.

12. The electronic apparatus as claimed in claim 9, wherein said case component is made of polypropylene.
